(19) United States
(12) Patent Application Publication
(10) Pub. No.: US 2005/0139148 A1
(43) Pub. Date: Jun. 30, 2005

(54) Silicon purifying method, slag for purifying silicon and purified silicon

(76) Inventors: Hiroyasu Fujiwara, Kyoto-shi (JP); Ryotatsu Otsuka, Kawachinagano-shi (JP); Kenji Wada, Takarazuka-shi (JP); Toshiaki Fukuyama, Nara-shi (JP)

Correspondence Address: BIRCH STEWART KOLASCH & BIRCH, PO BOX 747, FALLS CHURCH, VA, 22040-0747, US

(21) Appl. No.: 10/503,304

(22) PCT Filed: Feb. 3, 2003
(86) PCT No.: PCT/JP03/01083

(30) Foreign Application Priority Data
Feb. 4, 2002 (JP) 2002-026759

(51) Int. Cl. C30B 15/00; C30B 21/06; C30B 27/02; C30B 28/10; C30B 30/04

(52) U.S. Cl. 117/13

(57) ABSTRACT

Method capable of preparing silicon having purity of about 6N applied to a solar cell efficiently at a low cost. Raw silicon containing boron and a slag are melted and a shaft is rotated by a rotating/driving mechanism for stirring the molten silicon. The molten slag is dispersed in the molten silicon, thereby accelerating the boron removal reaction. It is further effective to use a slag containing at least 45 percent by mass of silicon oxide or to blow gas mixed with water vapor into the molten silicon for refining reaction.

### TECHNICAL FIELD

The present invention generally relates to a method of purifying silicon, and more specifically, it relates to a method of preparing a silicon material for a solar cell.

### BACKGROUND ART

In general, a metallic element such as iron, aluminum, copper or silicon is extremely rarely present solely in nature, and most part thereof is present as a compound such as an oxide. In order to apply such a metallic element to a structural material, a conductive material or a semiconductor material, therefore, it is generally necessary to reduce an oxide or the like into the form of a simple metallic element.

If the oxide or the like is merely reduced, however, the quantities of impurities other than the desired simple metallic element are generally improper, and the quantities of the impurities are adjusted, mostly reduced in general. Such a step of reducing the quantities of impurities is referred to as purification.

The term purification denotes an operation of taking out impurities from a simple metallic element as other forms, and this object is attained by performing a proper physicochemical procedure in response to the physiochemical properties of the metal forming the matrix or impurity elements. Referring to a steel material most generally employed as a structural material, for example, a molten oxide referred to as a slag is brought into contact with pig iron taken out from a blast furnace for incorporating impurities such as phosphorus and sulfur remarkably damaging toughness thereby reducing the contents of phosphorus and sulfur in the pig iron.

As to carbon serving as an impurity element basically deciding the mechanical strength of the steel material, oxygen gas is blown into molten steel for oxidizing carbon contained in the molten steel and discharging the same as carbon dioxide gas, thereby adjusting the carbon content in the steel.

As to copper employed as one of general wire materials, purity is increased by the so-called unidirectional solidification of solidifying copper at a slow speed nearly bringing an equilibrium state through the property that the ratio between the impurity concentration in solid metal in the equilibrium and that in molten metal, i.e., the so-called segregation coefficient of the impurity is generally small, for preparing a wire material having a low electric resistance value.

As to silicon most generally employed as a semiconductor material, polycrystalline silicon having purity of 11N is obtained by converting metallic silicon of at least 98% in purity obtained by reducing silica stone to gas such as silane (SiH₄) or trichlorosilane (SiHCl₃) and hydrogen-reducing this gas in a bell jar furnace.

The polycrystalline silicon obtained in the aforementioned manner is grown in a single-crystalline manner, thereby preparing a silicon wafer employed for an electronic device such as an LSI. In order to satisfy requirements for application to the electronic device, extremely complicated fabrication steps and strict fabrication step management are required and hence the fabrication cost therefor must inevitably be increased.

As to silicon employed as a solar cell material rapidly increasingly demanded in recent years due to the high awareness related to the energy/environmental problems such as depletion of fossil fuel resources and global warming, on the other hand, purity required for exhibiting performance required to the solar cell is about 6N, and a nonstandard product of silicon for an electronic device heretofore used as a solar cell material has excess quality for serving as the solar cell material.

While the yield of nonstandard products for electronic devices has heretofore excelled the demand for solar cells, it is regarded certain that the demand for solar cells exceeds the yield of the nonstandard products for electronic devices in the near future, and establishment of a low-priced fabrication technique for silicon serving as a solar cell material is strongly demanded. A technique of purifying the aforementioned metallic silicon of about 98% in purity through a metallurgical procedure utilizing oxidation-reduction reaction or solidification/segregation has recently been watched as means therefor.

Among impurities contained in silicon applied to a solar cell, elements, typically phosphorus and boron, deciding the conductivity type of the silicon must most strictly be controlled in content. However, it is known that these elements have extremely large segregation coefficients of about 0.35 and 0.8 respectively and hence purification utilizing solidification/segregation represented by the aforementioned unidirectional solidification is substantially ineffective.

As to phosphorus, there is a method of holding molten silicon under decompression-for discharging phosphorus into a gas phase through the characteristic of high vapor pressure, as disclosed in Japanese Patent No. 2905353, for example. As to boron, on the other hand, there is a method of applying a plasma of a gas mixture containing argon or gas obtained by adding hydrogen to argon, water vapor gas and silica powder to the surface of molten silicon as disclosed in Japanese Patent No. 3205352 or a method of immersing a torch burning hydrogen and oxygen while introducing silica powder in molten silicon as disclosed in U.S. Pat. No. 5,972,107.

Japanese Patent Laying-Open No. 2001-58811 discloses a method of stirring a molten bath of silicon with a rotating turbine wheel or through Lorenz force for blowing gas introduced for refining reaction such as argon containing water vapor thereinto. Further, there is a method of continuously introducing a slag into molten silicon, as disclosed in Japanese Patent No. 2851257. Each method removes boron from molten silicon in the form of an oxide due to oxidation reaction in principle.

While the aforementioned methods can be listed in relation to purification of silicon through a metallurgical procedure, none of these methods is commercially valid under the present circumstances due to the problem of the cost. Referring to boron removal, the method of applying a plasma to the surface of molten silicon disclosed in Japanese Patent No. 3205352 or the method of immersing a torch in molten silicon disclosed in U.S. Pat. No. 5,972,107 has such a problem that a reaction site is so local that the obtainable throughput is limited and a device itself requires a high cost.

As to the method of introducing a slag mainly composed of CaO and SiO₂ into molten silicon disclosed in Japanese Patent No. 2851257, the ratio of the quantity of boron incorporated into the slag to the boron content in silicon, i.e., the so-called partition coefficient is about 2 to 3 and hence it follows that the slag must commercially unpractically be in a quantity several times the silicon quantity in order to set the boron concentration to about 0.3 ppm required for a solar cell when metallic silicon originally containing about 10 ppm to 50 ppm of boron is employed as the raw material therefor.

As to the method of stirring a molten bath of silicon with a rotating turbine wheel or through Lorenz force for blowing gas introduced for refining reaction such as argon containing water vapor thereinto disclosed in Japanese Patent Laying-Open No. 2001-58811, reduction of a device cost can be expected due to a simple device, while the reaction rate is not remarkably improved and there is still little prospect of commercialization.

### DISCLOSURE OF THE INVENTION

The principal object of the present invention is to provide a method of purifying an impurity element contained in metal such as silicon extremely efficiently through a low-priced process. In order to attain this object, a method of purifying silicon according to the present invention is characterized in holding silicon containing an impurity and a slag containing at least 45 percent by mass of SiO₂ in a molten state, blowing gas introduced for refining reaction containing at least one selected from a group consisting of water vapor, oxygen gas, oxygen-containing gas and halogen-based gas into the molten silicon and stirring the same.

According to the present invention, the gas introduced for refining reaction is preferably in a mode containing at least 2 percent by volume of at least one selected from the group consisting of water vapor, oxygen gas, oxygen-containing gas and halogen-based gas. Further, a mode of rotating a stirring part immersed in the molten silicon and a mode of providing an injection nozzle on the stirring part for blowing the gas introduced for refining reaction into the molten silicon from the injection nozzle are preferable.

The impurity may include either boron or carbon, and the slag preferably contains at least 60 percent by mass of SiO₂ while containing an alkaline metal oxide. Lithium oxide is preferable as the alkaline metal oxide. The molten slag is preferably added during purification, and a mode of adding a solid slag mainly consisting of SiO₂ during purification is preferable.

### BRIEF DESCRIPTION OF THE DRAWING

FIG. 1 is a conceptual diagram of an apparatus employed for carrying out purification according to the present invention.

### BEST ODES FOR CARRYING OUT THE INVENTION

An embodiment of the present invention is described with reference to a method of removing boron from molten silicon. However, the effect of the present invention is acceleration of oxidation reaction and hence the removed impurity element is not restricted to boron. Carbon can also be listed as a typical one among impurity elements removed by oxidation reaction.

In order to clarify the effect of the present invention, scrap silicon containing 65 ppm of boron was mixed into semiconductor-grade silicon having purity of 11N at a weight ratio of about 8:1. Consequently, silicon containing about 7 ppm of boron was obtained, and this was employed as raw silicon to be purified.

While the mixture of the semiconductor-grade silicon and the boron-containing scrap silicon was employed as the raw silicon, raw material containing an element other than boron, such as frequently industrially utilized metallic silicon having purity of about 98%, for example, also implements the effect of the present invention, as a matter of course.

In addition to the raw silicon, a mixture of silicon oxide (SiO₂) and calcium oxide (CaO) is simultaneously charged as a slag material into a crucible serving as a purification furnace. As understood from a binary system phase diagram of SiO₂—CaO described in Advanced Physical Chemistry for Process Metallurgy (Nobuo Sano et al., ACADEMIC PRESS, p 109, 1997), for example, a slag formed by a mixture of silicon oxide and calcium oxide can be brought into a molten state at a temperature of at least 1460° C. slightly higher than the melting point of 1414° C. of silicon.

For example, the aforementioned Japanese Patent No. 3205352 or U.S. Pat. No. 5,972,107 discloses that powder silicon oxide is useful as an oxidizer. However, the powder silicon oxide having inferior wettability with molten silicon cannot be introduced in a large quantity, and hence the purification speed is limited. Therefore, silicon oxide is added not in the form of powder but in the form of a molten slag, so that the oxidizer necessary for purification can be introduced in a large quantity.

Stirring was so performed as to disperse the molten slag in the molten silicon, for sufficiently deriving the function of the molten slag for serving as an oxidizer while suppressing the consumption thereof and remarkably increasing the boron removing speed. However, the slag may not be entirely molten but may be partially in a solid state, to attain a substantially similar effect.

When the slag mainly composed of CaO disclosed in the aforementioned Japanese Patent No. 2851257 is used as an SiO₂—CaO-based molten slag, for example, the necessary slag consumption is increased due to a weak function for serving as an oxidizer. Therefore, it is more preferable to use a slag mainly composed of silicon oxide having a strong function for serving as an oxidizer, more specifically a slag containing at least 45 percent by mass of silicon oxide as the slag for purifying silicon. Further, a slag containing at least 60 percent by mass of silicon oxide is particularly preferable.

While the quantity of the slag material in the present invention varies with the components of the slag material and impurities contained in the raw silicon or the like, the slag material is preferably blended by 5 percent by mass to 50 percent by mass with respect to raw silicon in general, and more preferably blended by 10 percent by mass to 30 percent by mass.

When silicon and a slag were completely molten by electromagnetic induction and gas introduced for refining reaction was thereafter blown into the mixture by an ordinary gas blowing method as described later with reference to comparative example 2, the molten slag remained precipitated on the bottom of a crucible although the molten silicon was stirred, and the boron removing speed was insufficient. This fact means that it is difficult to disperse a molten slag in molten silicon by ordinary gas blowing. This is conceivably because the viscosity of an SiO₂—CaO-based molten slag is about 1 Pa·s, which is overwhelmingly large as compared with the viscosity of 0.001 Pa·s of molten silicon.

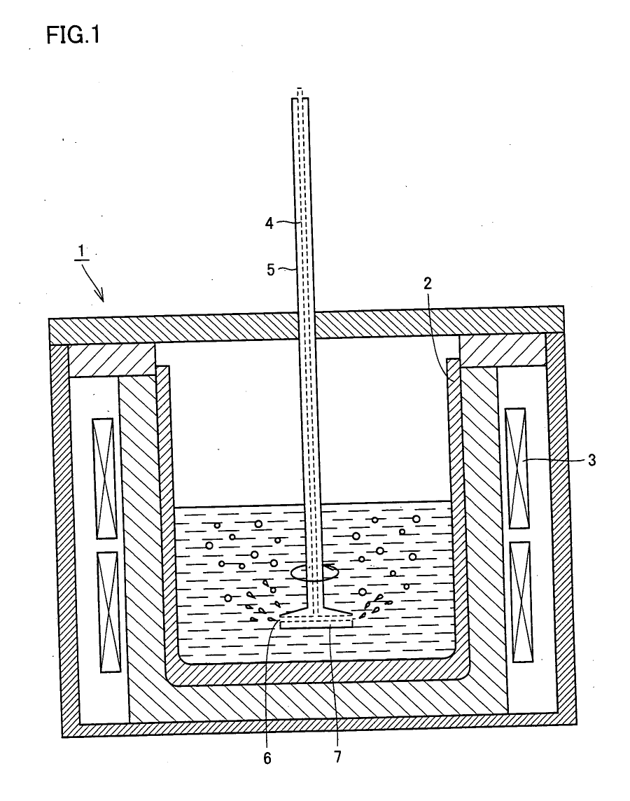

FIG. 1 shows an exemplary structure of an apparatus implementing a state of dispersing a molten slag in molten silicon. The wall of a smelting furnace 1 is made of stainless, and this smelting furnace 1 comprises a crucible 2 of graphite charged with raw silicon and a slag material, an electromagnetic induction heater 3, a shaft 5 and a stirring part 6 set on the lower portion of the shaft 5 therein.

A rotation/driving mechanism (not shown) is mounted on the upper portion of the shaft 5, for rotating the shaft 5 while immersing the stirring part 6 in the molten silicon and forming a fast stream in the molten silicon thereby refining the molten slag having high viscosity due to large shearing force caused on the contact parts of the molten silicon and the molten slag and dispersing the molten slag in the molten silicon. While the stirring part 6 is in the form of a turbine wheel, the shape is not restricted so far as the same can disperse the molten slag.

A portion of the shaft 5 passing through the wall of the smelting furnace 1 is provided with a sealing mechanism in order to ensure the sealing property in the smelting furnace 1 while rendering the shaft 5 rotatable. A hoisting mechanism (not shown) is provided on the upper end of the shaft 5 for immersing the stirring part 6 in the molten silicon stored in the crucible 2 in treatment and separating the stirring part 6 from the molten silicon before and after the treatment.

The shaft 5 is provided therein with a gas introduced for refining reaction introduction passage 4. Further, the stirring part 6 is provided with an injection nozzle 7 communicating with the gas introduced for refining reaction introduction passage 4. While the shaft 5 is provided with the gas introduced for refining reaction introduction passage 4 and the stirring part 6 is provided with the injection nozzle 7, the apparatus may not simultaneously be provided with these elements but may alternatively be provided with the shaft 5 and the stirring part 6 independently of a gas introduced for refining reaction introduction mechanism etc.

The boron removing speed can be further increased by blowing gas introduced for refining reaction containing water vapor into the molten silicon along with rotation of the shaft 5. The quantity of water vapor in the gas introduced for refining reaction can be controlled through a simple humidifier. For example, the quantity of water vapor can be easily controlled within the range of about 2% to 70% in volume ratio by typically setting the dew point of the gas to 20° C. to 90° C. Hydrogen gas may be properly added to this gas introduced for refining reaction.

The gas introduced for refining reaction is not limited to water vapor-containing gas but may naturally be oxygen gas, for example, or may be oxygen-containing gas such as carbon monoxide gas. Considering oxygen reaction in a broad sense, further, a similar effect can be expected to halogen-based gas such as hydrogen chloride. Inert gas, such as argon, for example, having small reactivity with silicon is particularly preferable as carrier gas, and nitrogen or the like is also usable.

A procedure of removing boron is now described. The smelting furnace 1 is brought into an inert gas atmosphere of argon or the like and the crucible 2 is heated with the electromagnetic induction heater 3, so that the raw silicon and the slag are increased in temperature due to heat conduction from the crucible 2 to be finally molten. A melt formed in this manner is held at a prescribed treatment temperature. In this stage, the molten silicon and the molten slag are completely separated from each other. At this time, several grams of the molten silicon is sampled so that the molten slag is not mixed thereinto, in order to measure the boron content before treatment.

The shaft 5 is moved down by the hoist mechanism for immersing the stirring part 6 in the molten silicon while injecting the gas introduced for refining reaction from the injection nozzle 7 of the stirring part 6 through the gas introduced for refining reaction introduction passage 4. At this time, the gas introduced for refining reaction introduction pressure is set larger than 1 atm. in the range of 0.15 to 0.3 MPa, for example, so that the gas introduced for refining reaction can be stably continuously injected also when the molten slag having high viscosity is mixed into the same.

The stirring part 6 is moved down to the lower portion of the molten silicon, preferably to a portion around the interface between the molten slag and the molten silicon, and the shaft 5 is thereafter rotated through the rotation/driving mechanism. Bubbles of the gas introduced for refining reaction injected from the injection nozzle 7 and the molten slag are fined and dispersed due to the rotation of the shaft 5. Further, the three phases of the gas introduced for refining reaction, the molten slag and the molten silicon are extremely efficiently mixed with each other, and the contact areas between the respective phases are remarkably increased. In this state, oxidation reaction of boron in the molten silicon is remarkably accelerated by water vapor contained in the gas introduced for refining reaction and oxygen supplied from the molten slag.

It is conceivable that a boron oxide such as B₂O₃ incorporated into the molten slag reacts with the water vapor contained in the gas introduced for refining reaction to be discharged from the reaction system as boron-containing gas such as HBO₂, for example, thereby allowing continuation of purification.

The oxidation reaction is so remarkably accelerated that the consumption of silicon oxide contained in the slag serving as an oxidizer is also accelerated. Therefore, it is effective to add a molten slag mainly composed of silicon oxide or powder mainly composed of silicon oxide during purification, in order to reduce the time required for purification. While the procedure disclosed in the aforementioned Japanese Patent No. 2851257 is also a method of adding a slag during purification, the treatment time is remarkably reduced in the method according to the present invention, whereby the quantity of the slag necessary for purification can be extremely suppressed.

Development of the effect of the present invention is not restricted to a binary system slag of SiO₂—CaO, as a matter of course. An additive such as aluminum oxide (Al₂O₃), magnesium oxide (MgO), barium oxide (BaO) or calcium fluoride (CaF₂) generally employed in the field of refinement of steel or the like may be properly added in order to attain various objects such as adjustment of the melting point or the viscosity, for example. In the present invention, it is preferable to reduce the melting point or the viscosity without remarkably damaging the effect of the slag serving as an oxidizer.

For this purpose, calcium oxide is preferably partially or entirely replaced with an alkaline metal-based oxide such as lithium oxide or sodium oxide (Na₂O). A preferable content of the alkaline metal-based oxide is 1 percent by mass to 20 percent by mass, more preferably 3 percent by mass to 10 percent by mass with respect to the slag. If the content is smaller than 1 percent by mass, it is difficult to sufficiently reduce the melting point or the viscosity. If the content is larger than 20 percent by mass, on the other hand, the effect of the slag serving as an oxidizer tends to be insufficient.

While an alkaline metal-based oxide may be used as the raw material for the slag in order to add the alkaline metal-based oxide to the slag, the alkaline metal-based oxide presents strong alkalinity when converted to hydroxide upon reaction with water and must be carefully handled. Therefore, an easily handled substance is desirably used as the raw material for the slag. Carbonate, hydrogen carbonate or silicate of alkaline metal can be listed as such a raw material for the slag. For example, Li₂CO₃, LiHCO₃ or Li₂SiO₄ may be added as the raw material for the slag in place of SiO₂, for attaining an effect similar to that of adding Li₂O to a slag containing SiO₂. When adding Na₂O, it is preferable to use Na₂CO₃, NaHCO₃ or Na₂SiO₄ as the raw material for the slag.

A preferable content of carbonate, hydrogen carbonate or silicate of the alkaline metal is 2 percent by mass to 60 percent by mass, more preferably 5 percent by mass to 30 percent by mass with respect to the slag. If this content is smaller than 2 percent by mass, it is difficult to sufficiently reduce the melting point or the viscosity. If the content is larger than 60 percent by mass, on the other hand, the effect of the slag serving as an oxidizer tends to be insufficient.

After the treatment is performed for a prescribed time, the shaft 5 is moved up with the hoist mechanism until the stirring part 6 is located sufficiently above the surface of the molten silicon. The substance is stood still for several minutes for sufficiently separating the molten silicon and the molten slag from each other, and the molten silicon is taken out by about several grams so that no molten slag is mixed thereinto, in order to measure the boron content after the treatment. The boron content was measured by inductively coupled plasma spectrometry.

The inventive silicon is purified with this slag and prepared by the aforementioned purification method. It is possible to prepare silicon having purity of about 6N applied to a solar cell efficiently at a low cost.

### REFERENCE EXAMPLE 1

In this Example, a substance obtained by mixing silicon oxide powder and calcium oxide powder at a weight ratio of 65:35 was used as a slag material. Then, 1 kg of a substance obtained by blending raw silicon having a boron concentration adjusted to 7 ppm and the slag material with each other at a weight ratio of 4:1 was charged into the crucible 2. The smelting furnace 1 was set to an argon gas atmosphere of 1 atm, and the crucible 2 was thereafter heated with the electromagnetic induction heater 3 thereby melting the raw silicon and the slag material, which in turn were thereafter held at 1550° C.

The molten slag, having large specific gravity with respect to the molten silicon, precipitated on the bottom of the crucible 2. The shaft 5 was moved down through the hoist mechanism until the injection nozzle 7 of the stirring part 6 reached the portion around the interface between the molten slag and the molten silicon. When the shaft 5 was rotated at 400 rpm without gas introduced for refining reaction, the contents of the crucible 2 were so stirred that the molten slag was dispersed into the molten silicon. When the boron content around the treatment was measured after performing the treatment for 2 hours, that before the treatment was 7.0 ppm and that after the treatment was 1.6 ppm.

### REFERENCE EXAMPLE 2

Treatment was performed for two hours under conditions similar to those for Reference Example 1 except that the shaft 5 was rotated at 400 rpm while injecting argon gas from the injection nozzle 7 of the stirring part 6 at a flow velocity of 1 L/min. When the boron content was measured around the treatment, that before the treatment was 7.4 ppm and that after the treatment was 1.3 ppm.

### EXAMPLE 1

Treatment was performed for two hours under conditions similar to those for Reference Example 1 except that the shaft 5 was rotated at 400 rpm while injecting gas introduced for refining reaction prepared by setting a water vapor content in argon gas to 30% from the injection nozzle 7 of the stirring part 6 at a flow velocity of 1 L/min. When the boron content was measured around the treatment, that before the treatment was 7.4 ppm and that after the treatment was 0.8 ppm.

### EXAMPLE 2

Treatment was performed for two hours under conditions similar to those for Example 1 except that the shaft 5 was rotated at 600 rpm while blending raw silicon having a boron concentration adjusted to 7 ppm and a slag material with each other at a weight ratio of 9:1 and injecting gas introduced for refining reaction from the injection nozzle 7 of the stirring part 6 at a flow velocity of 3 L/min. When the boron content was measured around the treatment, that before the treatment was 7.2 ppm and that after the treatment was 0.6 ppm.

### EXAMPLE 3

Treatment was performed for two hours similarly to Example 1, except that a substance obtained by mixing silicon oxide powder and calcium oxide powder with each other at a weight ratio of 45:55 was used as a slag material. When the boron content was measured around the treatment, that before the treatment was 7.8 ppm and that after the treatment was 1.8 ppm.

### EXAMPLE 4

Treatment was performed for two hours under conditions similar to those for Example 1 except that a substance obtained by mixing powder materials of silicon oxide, calcium oxide, magnesium oxide and lithium oxide with each other at weight ratios of 70:10:10:10 was used as a slag material. When the boron content was measured around the treatment, that before the treatment was 7.3 ppm and that after the treatment was 0.5 ppm.

### COMPARATIVE EXAMPLE 1

Treatment was performed for two hours under conditions similar to those for Example 1 except that no slag material was introduced. When the boron content was measured around the treatment, that before the treatment was 7.4 ppm and that after the treatment was 4.4 ppm.

### COMPARATIVE EXAMPLE 2

Treatment was performed for two hours under conditions similar to those for Example 1 except that the shaft 5 was not rotated and no stirring was made. When the boron content was measured around the treatment, that before the treatment was 7.5 ppm and that after the treatment was 3.6 ppm.

### EXAMPLE 5

Treatment was performed for two hours under conditions similar to those for Example 2 except that 100 g of a slag material obtained by mixing silicon oxide powder and calcium oxide powder with each other at a weight ratio of 65:35 was additionally charged into the crucible 2 after one hour from starting the treatment. When the boron content was measured around the treatment, that before the treatment was 7.6 ppm and that after the treatment was 0.3 ppm.

Application of the present invention is not restricted to these Examples but the content of the slag material, the flow rate of the gas introduced for refining reaction, the rotational frequency of the shaft and the like must be properly selected to be in optimum states in response to the quantity of raw silicon to be treated or the shape of the crucible.

The embodiment and Examples disclosed this time are to be considered as illustrative and not restrictive in all points. The scope of the present invention is shown not by the above description but by the scope of claim for patent, and it is intended that all modifications within the meaning and range equivalent to the scope of claim for patent are included.

### Industrial Availability

According to the present invention, ability of removing boron from molten silicon is remarkably improved by adding a slag in an extremely small quantity as compared with the prior art.

1. A method of purifying silicon by holding silicon containing an impurity and a slag containing at least 45 percent by mass of SiO₂ in a molten state, blowing gas introduced for refining reaction containing at least one substance selected from a group consisting of water vapor, oxygen gas, oxygen-containing gas and halogen-based gas into the molten silicon and stirring the silicon and the slag.

2. The method of purifying silicon according to claim 1, wherein said gas introduced for refining reaction contains at least 2 percent by volume of at least one substance selected from the group consisting of water vapor, oxygen gas, oxygen-containing gas and halogen-based gas.

3. (canceled)

4. (canceled)

5. The method of purifying silicon according to claim 1, comprising rotating a stirring part immersed in the molten silicon.

6. The method of purifying silicon according to claim 5, comprising providing said stirring part with an injection nozzle and blowing the gas introduced for refining reaction into the molten silicon from said injection nozzle.

7. The method of purifying silicon according to claim 1, wherein said impurity includes either boron or carbon.

8. The method of purifying silicon according to claim 1, wherein said slag contains at least 60 percent by mass of SiO₂.

9. The method of purifying silicon according to claim 1, wherein said slag contains an alkaline metal oxide.

10. The method of purifying silicon according to claim 9, wherein said slag contains lithium oxide.

11. The method of purifying silicon according to claim 1, comprising adding said molten slag during purification.

12. The method of purifying silicon according to claim 1, comprising adding a solid slag mainly consisting of SiO₂ during purification.

13. (canceled)

14. (canceled)

15. (canceled)
